(19) United States
(12) Patent Application Publication
(10) Pub. No.: US 2014/0051239 A1
(43) Pub. Date: Feb. 20, 2014

(54) DISPOSABLE CARBON-BASED TEMPLATE LAYER FOR FORMATION OF BORDERLESS CONTACT STRUCTURES

(71) Applicants: Gregory Breyta, San Jose, CA (US); Josephine B. Chang, Mahopac, NY (US); Sebastian U. Engelmann, New York, NY (US); Michael A. Guillorn, Yorktown Heights, NY (US); David P. Klaus, Yorktown Heights, NY (US); Adam M. Pyzyna, Cortlandt Manor, NY (US)

(72) Inventors: Gregory Breyta, San Jose, CA (US); Josephine B. Chang, Mahopac, NY (US); Sebastian U. Engelmann, New York, NY (US); Michael A. Guillorn, Yorktown Heights, NY (US); David P. Klaus, Yorktown Heights, NY (US); Adam M. Pyzyna, Cortlandt Manor, NY (US)

(73) Assignee: INTERNATIONAL BUSINESS MACHINES CORPORATION, Armonk, NY (US)

(21) Appl. No.: 13/585,337

(22) Filed: Aug. 14, 2012

(51) Int. Cl. H01L 21/28

(52) U.S. Cl. 438/586; 257/E21.176

(57) ABSTRACT

After formation of gate stacks, a carbon-based template layer is deposited over the gate stacks, and is optionally planarized to provide a planar top surface. A hard mask layer and a photoresist layer are subsequently formed above the carbon-based template layer. A pattern including openings is formed within the photoresist layer. The pattern is subsequently transferred through the hard mask layer and the carbon-based template layer with high selectivity to gate spacers to form self-aligned cavities within the carbon-based template layer. Contact structures are formed within the carbon-based template layer by a damascene method. The hard mask layer and the carbon-based template layer are subsequently removed selective to the contact structures. The contact structures can be formed as contact bar structures or contact via structures. Optionally, a contact-level dielectric layer can be subsequently deposited.

### BACKGROUND

The present disclosure relates to semiconductor structures, and particularly to a method of forming borderless contact structures employing a disposable carbon-based template layer, and structures formed by the same.

As semiconductor devices shrink in each generation of semiconductor technology, formation of contact structures to source and drain regions and gate electrodes of a field effect transistor become challenging because such contact structures not only need to provide reliable electrical contact to the source and drain regions or the gate electrodes, but also need to avoid electrically shorting to other components or among themselves. Common integration schemes for forming self-aligned contact structures employs silicon oxide and silicon nitride, which do not provide high selectivity during an etch that forms contact via holes, thereby providing a non-negligible probability of electrical shorts between a contact via structure and a gate electrode.

As the gate pitch of complementary metal-oxide-semiconductor (CMOS) integrated circuits decreases, the size and pitch of contact structures must scale accordingly and, consequently, the alignment tolerance for the contact structures with respect to the gate electrode also shrinks. Gross misalignment of the contact structures may result in gate-to-source/drain shorts, thereby rendering the underlying devices inoperable. As the gate pitch shrinks below 80 nm, the incorporation of the gate electrode, sidewall spacers and the contact structures reduces the overlay tolerance to a point where the formation of self-aligned contact structures or local interconnect structures becomes necessary to continue technology scaling.

### SUMMARY

After formation of gate stacks, a carbon-based template layer can be deposited over the gate stacks, and can be optionally planarized to provide a planar top surface. A hard mask layer and a photoresist layer are subsequently formed above the carbon-based template layer. A pattern including openings is formed within the photoresist layer. The pattern is subsequently transferred through the hard mask layer and the carbon-based template layer with high selectivity to gate spacers to form self-aligned cavities within the carbon-based template layer. Contact structures are formed within the carbon-based template layer by a damascene method. The hard mask layer and the carbon-based template layer are subsequently removed selective to the contact structures. The contact structures can be formed as contact bar structures or contact via structures. Optionally, a contact-level dielectric layer can be subsequently deposited.

According to an aspect of the present disclosure, a method of forming a semiconductor structure is provided. A plurality of protruding structures is formed on a semiconductor substrate. Each of the plurality of protruding structures includes a conductive structure and a dielectric spacer laterally surrounding the conductive structure. A stack of a carbon-based template layer and a dielectric hard mask layer is formed over the semiconductor substrate. The stack is patterned by forming at least one opening therein. Each of the at least one opening extends from a top surface of the dielectric hard mask layer to a top surface of the substrate. A conductive material layer is formed over an entirety of the stack and within the at least one opening and directly on a portion of the top surface of the substrate.

According to another aspect of the present disclosure, a semiconductor structure is provided. The semiconductor structure includes a first protruding structure located on a semiconductor substrate, and including a first conductive structure and a first dielectric spacer laterally surrounding the first conductive structure. The semiconductor structure further includes a second protruding structure located on the semiconductor substrate, and including a second conductive structure and a second dielectric spacer laterally surrounding the second conductive structure. In addition, the semiconductor structure includes a conductive material portion in contact a sidewall of the first dielectric spacer, and a sidewall of the second dielectric spacer, and vertically extending from a top surface of the semiconductor substrate and at least to a topmost surface of the first and second protruding structures.

According to another aspect of the present disclosure, another semiconductor structure is provided. The semiconductor structure includes a plurality of protruding structures located on a semiconductor substrate. Each of the plurality of protruding structure includes a conductive structure and a dielectric spacer laterally surrounding the conductive structure. The semiconductor structure further includes a stack of a carbon-based template layer and a dielectric hard mask layer, the stack including at least one opening therein. Each of the at least one opening extends to a portion of a top surface of the substrate located between a pair of the plurality of protruding structures. The carbon-based template layer has a planar top surface located above a topmost surface of the plurality of protruding structures. A conductive material layer contiguously covers an entirety of the stack and filling the at least one opening and contacts the portion of the top surface of the substrate.

### BRIEF DESCRIPTION OF THE SEVERAL VIEWS OF THE DRAWINGS

FIG. 1A is top-down view of a first exemplary semiconductor structure after formation of gate stacks and gate spacers according to a first embodiment of the present disclosure.

FIG. 1B is a vertical cross-sectional view of the first exemplary semiconductor structure of FIG. 1A.

FIG. 2A is a top-down view of the first exemplary semiconductor structure after deposition of a carbon-based template layer, a hard mask layer, and a photoresist layer according to the first embodiment of the present disclosure.

FIG. 2B is a vertical cross-sectional view of the first exemplary semiconductor structure of FIG. 2A.

FIG. 3A is a top-down view of the first exemplary semiconductor structure after lithographic patterning of the photoresist layer according to the first embodiment of the present disclosure.

FIG. 3B is a vertical cross-sectional view of the first exemplary semiconductor structure of FIG. 3A.

FIG. 4A is a top-down view of the first exemplary semiconductor structure after transferring the pattern in the photoresist layer through the hard mask layer and the carbon-based template layer and removal of the photoresist layer according to the first embodiment of the present disclosure.

FIG. 4B is a vertical cross-sectional view of the first exemplary semiconductor structure of FIG. 4A.

FIG. 5A is a top-down view of the first exemplary semiconductor structure after deposition of at least one conductive material within cavities in the hard mask layer and the carbon-based template layer according to the first embodiment of the present disclosure.

FIG. 5B is a vertical cross-sectional view of the first exemplary semiconductor structure of FIG. 5A.

FIG. 6A is a top-down view of the first exemplary semiconductor structure after planarization of the at least one conductive material according to the first embodiment of the present disclosure.

FIG. 6B is a vertical cross-sectional view of the first exemplary semiconductor structure of FIG. 6A.

FIG. 7A is a top-down view of the first exemplary semiconductor structure after removal of the carbon-based template layer according to the first embodiment of the present disclosure.

FIG. 7B is a vertical cross-sectional view of the first exemplary semiconductor structure of FIG. 7A.

FIG. 8A is a top-down view of the first exemplary semiconductor structure after deposition of a contact-level dielectric layer and formation of various contact via structures according to the first embodiment of the present disclosure.

FIG. 8B is a vertical cross-sectional view of the first exemplary semiconductor structure of FIG. 8A.

FIG. 9A is a top-down view of a variation of the first exemplary semiconductor structure after formation of disposable gate structures, dielectric spacers, and a planarization material layer and planarization of the planarization material layer according to the first embodiment of the present disclosure.

FIG. 9B is a vertical cross-sectional view of the variation of the first exemplary structure of FIG. 9A.

FIG. 10A is a top-down view of a variation of the first exemplary semiconductor structure after formation of replacement gate stacks according to the first embodiment of the present disclosure.

FIG. 10B is a vertical cross-sectional view of the variation of the first exemplary structure of FIG. 10A.

FIG. 11A is a top-down view of the variation of the first exemplary semiconductor structure after deposition of a contact-level dielectric layer and formation of various contact via structures according to the first embodiment of the present disclosure.

FIG. 11B is a vertical cross-sectional view of the variation of the first exemplary semiconductor structure of FIG. 11A.

FIG. 12A is a top-down view of a second exemplary semiconductor structure after lithographic patterning of a photoresist layer according to a second embodiment of the present disclosure.

FIG. 12B is a vertical cross-sectional view of the second exemplary semiconductor structure of FIG. 12A.

FIG. 13A is a top-down view of the second exemplary semiconductor structure after transferring the pattern in the photoresist layer through the hard mask layer and the carbon-based template layer and removal of the photoresist layer according to the second embodiment of the present disclosure.

FIG. 13B is a vertical cross-sectional view of the second exemplary semiconductor structure of FIG. 13A.

FIG. 14A is a top-down view of the second exemplary semiconductor structure after deposition of at least one conductive material within cavities in the hard mask layer and the carbon-based template layer according to the second embodiment of the present disclosure.

FIG. 14B is a vertical cross-sectional view of the second exemplary semiconductor structure of FIG. 14A.

FIG. 15A is a top-down view of the second exemplary semiconductor structure after planarization of the at least one conductive material according to the second embodiment of the present disclosure.

FIG. 15B is a vertical cross-sectional view of the second exemplary semiconductor structure of FIG. 15A.

FIG. 16A is a top-down view of the second exemplary semiconductor structure after removal of the carbon-based template layer according to the second embodiment of the present disclosure.

FIG. 16B is a vertical cross-sectional view of the second exemplary semiconductor structure of FIG. 16A.

FIG. 17A is a top-down view of the second exemplary semiconductor structure after deposition of a contact-level dielectric layer according to the second embodiment of the present disclosure.

FIG. 17B is a vertical cross-sectional view of the second exemplary semiconductor structure of FIG. 17A.

FIG. 18A is a top-down view of a variation of the second exemplary semiconductor structure according to the second embodiment of the present disclosure.

FIG. 18B is a vertical cross-sectional view of the variation of the second exemplary semiconductor structure of FIG. 18A.

### DETAILED DESCRIPTION

As stated above, the present disclosure relates to a method of forming borderless contact structures employing a disposable carbon-based template layer, and structures formed by the same, which are now described in detail with accompanying figures. Like and corresponding elements mentioned herein and illustrated in the drawings are referred to by like reference numerals. The drawings are not necessarily drawn to scale.

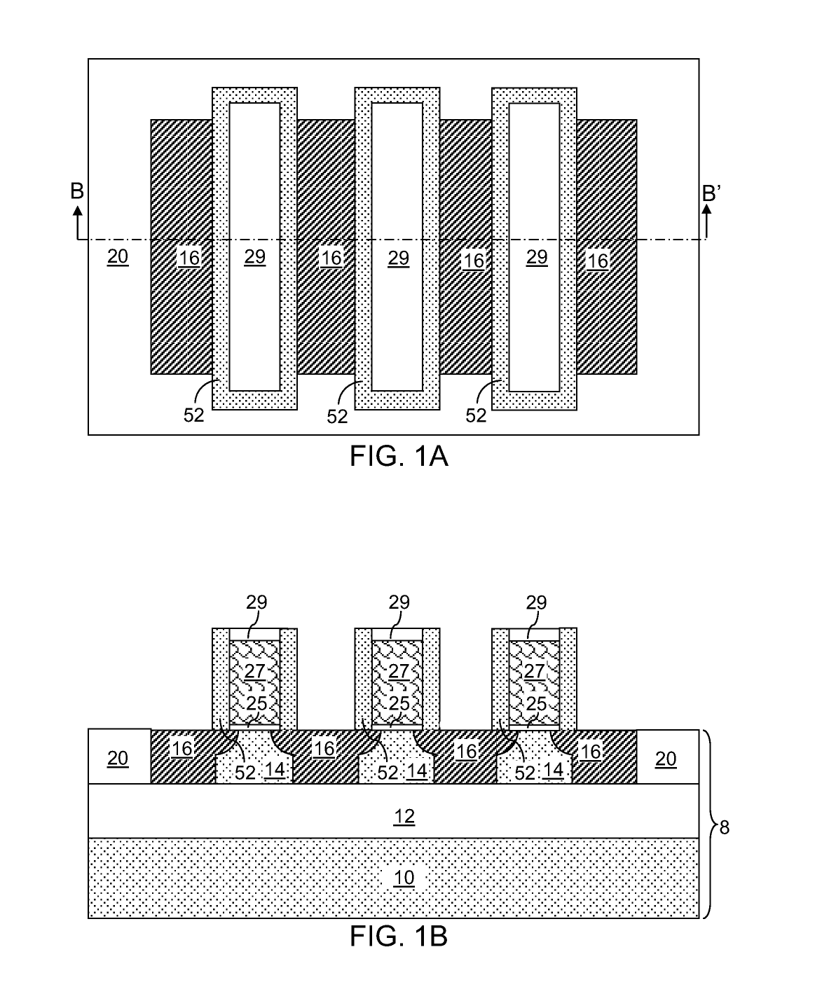

Referring to FIGS. 1A and 1B, a first exemplary semiconductor structure according to a first embodiment of the present disclosure includes a semiconductor substrate 8. The semiconductor substrate 8 can be a semiconductor-on-insulator (SOI) substrate including a stack, from bottom to top, of a handle substrate 10, a buried insulator layer 12, and a top semiconductor layer, or can be a bulk semiconductor substrate. At least one shallow trench isolation structure 20 can be formed within the top semiconductor layer or in an upper portion of the bulk semiconductor substrate.

Various semiconductor devices including at least one field effect transistor can be formed on the top semiconductor layer or on the upper portion of the bulk semiconductor substrate. For example, various source/drain regions 16 can be formed within the top semiconductor layer or within the upper portion of the bulk semiconductor substrate by introducing electrical dopants of p-type or n-type, for example, by ion implantation. As used herein a “source/drain region” refers to a region that functions as a source region and/or as a drain region of a field effect transistor, and includes a deep source region, a deep drain region, a source extension region, a drain extension region, a raised source region, and a raised drain region as known in the art. Body regions 14 are formed within the top semiconductor layer or the upper portion of the bulk semiconductor substrate. Each body region 14 can include a channel region of a field effect transistor.

A plurality of protruding structures is formed on the top surface of the semiconductor substrate 8. The semiconductor substrate 8 can have a planar top surface that is substantially planar throughout the entirety thereof, and the plurality of protruding structures can protrude above the planar top surface of the semiconductor substrate 8. For example, each of the plurality of protruding structures can include a conductive structure and a dielectric spacer laterally surrounding the conductive structure. As used herein, a “protruding structure” can be any structure that is located above a planar surface and does not cover the entirety of the planar surface. In one embodiment, a dielectric cap structure can be provided over the conductive structure.

In one embodiment, at least one of the plurality of protruding structures can include at least a gate dielectric 25 and a gate electrode 27 on top thereof. In one embodiment, each of the plurality of protruding structures can include at least a gate dielectric 25 and a gate electrode 27. In one embodiment, each of the plurality of protruding structures can further include a gate cap dielectric 29 located on a top surface of an underlying gate electrode 27. In one embodiment, each of the plurality of protruding structures can include a vertical stack, from bottom to top, of a gate dielectric 25, a gate electrode 27, and a gate cap dielectric 29 such that sidewall surfaces of the gate dielectric 25, the gate electrode 27, and the gate cap dielectric 29 are vertically coincident. As used herein, sidewalls of multiple elements are “vertically coincident” if the sidewalls are within a same vertical plane.

In one embodiment, stacks of the gate dielectric 25, the gate electrode 27, and the gate cap dielectric 29 can be provided by forming a planar gate dielectric layer on the top surface of the semiconductor substrate 8 by deposition and/or conversion of a surface portion of the top semiconductor layer or the upper portion of the bulk semiconductor substrate, by depositing a planar gate electrode layer on the planar gate dielectric layer, by depositing a planar gate cap dielectric layer including a dielectric material, and by patterning the planar gate cap dielectric layer, the planar gate electrode layer, and the planar gate dielectric layer. As used herein, a “planar” layer is a layer vertically extending between a horizontal top surface and a horizontal bottom surface that extend over the entirety of a substrate. The remaining portions of the planar gate electrode layer constitute the conductive structures, which are the gate electrodes 27.

The planar gate dielectric layer and the gate dielectrics 25 can include a dielectric material derived from the semiconductor material in the semiconductor substrate 8. For example, the planar gate dielectric layer and the gate dielectrics 25 can include silicon oxide, silicon nitride, and/or silicon oxynitride. Alternately or additionally, the material of the planar gate dielectric layer and the gate dielectrics 25 can include a dielectric metal oxide, a dielectric metal nitride, a dielectric metal oxynitride, or combinations thereof. Examples of dielectric metal oxides include HfO₂, ZrO₂, Al₂O₃, and LaO₂.

The planar gate electrode layer and the gate electrodes 27 can include at least one conductive material, which can be at least one doped semiconductor material and/or at least one metallic material. For example, the planar gate electrode layer and the gate electrodes 27 can include doped silicon, doped germanium, a doped silicon-germanium alloy, TiN, TaN, TaC, W, WN, or combinations thereof.

The planar gate cap dielectric layer and the gate cap dielectrics 29 can include a dielectric material such as silicon nitride, silicon oxide, and/or a dielectric metal oxide such as HfO₂, ZrO₂, Al₂O₃, and LaO₂.

Each of the plurality of protruding structures can include a dielectric spacer 52 laterally surrounding the conductive structure. The dielectric spacers 52 can be formed, for example, by depositing a conformal dielectric material layer on sidewalls of the conductive structures such as the gate electrodes 27, and by removing horizontal portions of the conformal dielectric material layer by anisotropically etching the conductive material layer. Remaining portions of the conductive material layer constitute the dielectric spacers 52. Portions of the top surfaces of the semiconductor substrate 8 such as top surfaces of the source/drain regions 16 are physically exposed between a pair of the plurality of protruding structures.

The dielectric spacer 52 can include a dielectric material such as silicon nitride, silicon oxide, HfO₂, ZrO₂, Al₂O₃, LaO₂, CN, BN, and BCN. The width of the dielectric spacers 52, as measured at the base that contacts the semiconductor substrate 8, can be from 5 nm to 100 nm, although lesser and greater widths can also be employed.

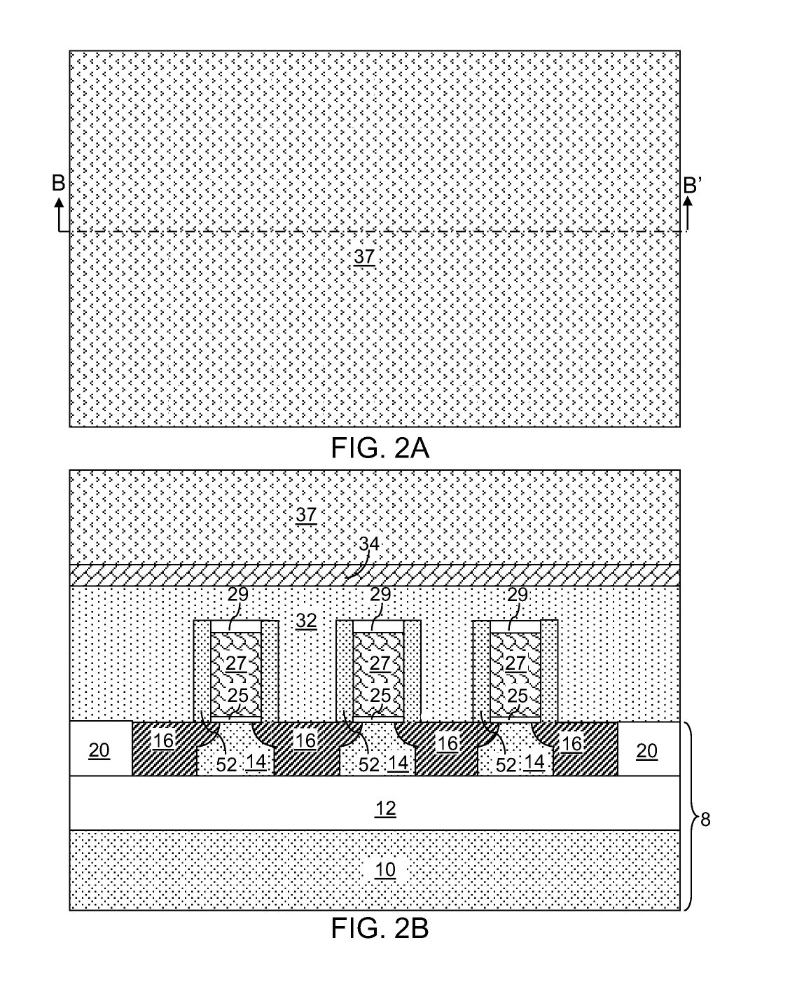

Referring to FIGS. 2A and 2B, a carbon-based template layer 32 is deposited over the semiconductor substrate 8 and the plurality of protruding structures (25, 27, 29, 52). The carbon-based template layer 32 can include an inorganic carbon-containing material or an organic carbon-containing material. The carbon-based template layer 32 can be formed, for example, by chemical vapor deposition (CVD) or spin-coating. In one embodiment, the carbon-based template layer 32 is deposited or spin-coated at a temperature not less than the temperature at which a dielectric hard mask layer 34 is subsequently deposited. In another embodiment, the carbon-based template layer 32 can be deposited or spin-coated at a temperature less than the temperature at which a dielectric hard mask layer 34 is subsequently deposited, and can be cured at a temperature not less than the temperature at which the dielectric hard mask layer 34 is subsequently deposited. In one embodiment, the carbon-based template layer 32 can be deposited or cured at a temperature in a range from 200° C. to 600° C. In another embodiment, the carbon-based template layer 32 can be deposited or cured at a temperature in a range from 200° C. to 500° C. In yet another embodiment, the carbon-based template layer 32 can be deposited or cured at a temperature in a range from 400° C. to 500° C.

In one embodiment, the carbon-based template layer 32 includes an inorganic carbon-containing material. In one embodiment, the carbon-based template layer 32 can consist essentially of an inorganic carbon material. For example, the carbon-based template layer 32 includes at least one of diamond-like carbon (DLC) and amorphous carbon.

In one embodiment, the carbon-based template layer 32 can include an inorganic carbon-containing compound. In one embodiment, the carbon-based template layer 32 can consist essentially of an inorganic carbon-containing compound. In one embodiment, the carbon-based template layer 32 can include carbon nitride. In one embodiment, the carbon-based template layer 32 can consist essentially of carbon nitride.

In one embodiment, the carbon-based template layer 32 can include an organic material. In one embodiment, the carbon-based template layer 32 can include an organic carbon-containing polymer. In one embodiment, the carbon-based template layer 32 can include a polymer selected from a naphthalene-based polymer, a cured poly(aryl acetylene) polymer or oligomer, a cured poly(aryl diacetylene) polymer or oligomer (such as cyclohexanol terminated poly(phenyl bisacetylene) (PBCH) polymer), a polyimide-based polymer, and a fluororocarbon-based polymer. In one embodiment, the carbon-based template layer 32 can consist essentially of at least one polymer selected from naphthalene-based polymer, a cured poly(aryl acetylene) polymer or oligomer, a cured poly(aryl diacetylene) polymer or oligomer (such as cyclohexanol terminated poly(phenyl bisacetylene) (PBCH) polymer), a polyimide-based polymer, and a fluororocarbon-based polymer. An example of a naphthalene-based polymer is HM8014™ by JSR™ and CHM901B™ by Cheil™.

The carbon-based template layer 32 can be self-planarizing, or can be planarized, for example, by chemical mechanical planarization (CMP) after deposition. A planar top surface of the carbon-based template layer 32 is located at or above the topmost surfaces of the gate cap dielectrics 29. The distance between the planar top surface of the carbon-based template layer 32 and the gate cap dielectrics 29 can be from 0 nm to 100 nm, although lesser and greater thicknesses can also be employed.

A dielectric hard mask layer 34 can be deposited over the carbon-based template layer 32. The dielectric hard mask layer 34 includes a dielectric material such as silicon oxide, silicon nitride, a dielectric metal oxide such as HfO₂, ZrO₂, Al₂O₃, and LaO₂, TaN, TiN, a silicon-containing anti-reflective coating (Si-ARC) material as known in the art, and combinations thereof. In one embodiment, the dielectric hard mask layer 34 includes a dielectric material selected from silicon nitride, a dielectric metal oxide, a Si-ARC material, TaN, and combinations thereof. In one embodiment, the dielectric hard mask layer 34 includes TaN. The thickness of the dielectric hard mask layer 34 can be from 2 nm to 20 nm, although lesser and greater thicknesses can also be employed.

A photoresist layer 37 is applied over the dielectric hard mask layer 34. The photoresist layer 37 can include any photoresist material known in the art. The thickness of the photoresist layer 37 can be from 200 nm to 1,000 nm, although lesser and greater thicknesses can also be employed.

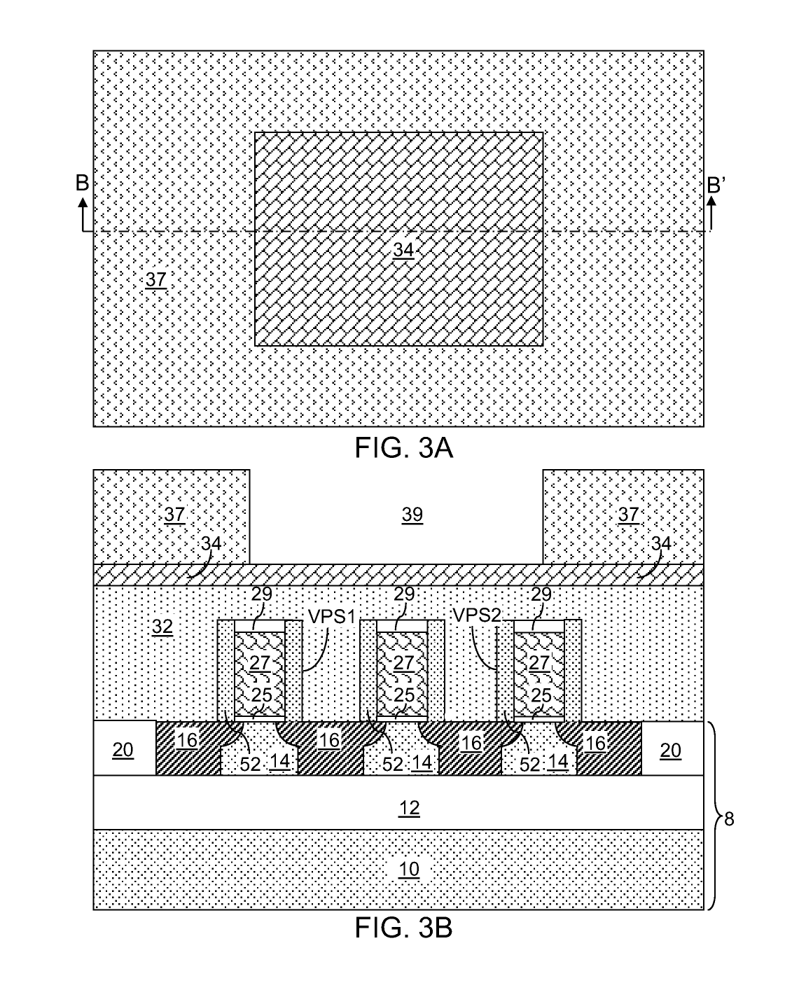

Referring to FIGS. 3A and 3B, at least one opening 39 is formed in the photoresist layer 37 by lithographic exposure and development. The pattern of the at least one opening 39 is selected such that the area of each opening 39 overlies a surface portion of the semiconductor substrate 8 that contacts the carbon-based template layer 32. In other words, the area of each opening 39 can overlie a portion of an interface between the semiconductor substrate 8 and the carbon-based template layer 32. In one embodiment, an area of an opening 39 can include an area that laterally extends from a first vertical planar sidewall VPS1 of a first dielectric spacer 52 within a first protruding structure (25, 27, 29, 52) to a second vertical planar sidewall VPS2 of a second dielectric spacer 52 within a second protruding structure (25, 27, 29, 52) that is laterally spaced from the first protruding structure (25, 27, 29, 52) at least by an interface between the semiconductor substrate 8 and the carbon-based template layer 32.

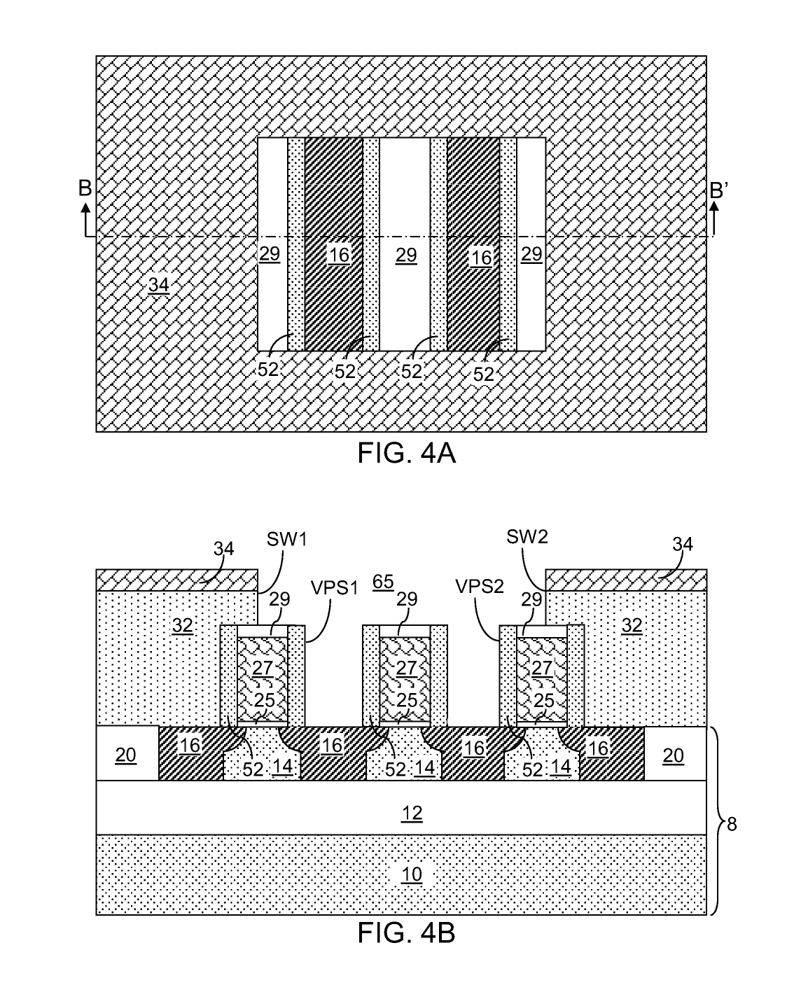

Referring to FIGS. 4A and 4B, the pattern in the photoresist layer 37 is transferred through the dielectric hard mask layer 34 and the carbon-based template layer 32 by an anisotropic etch, which can be a reactive ion etch.

In one embodiment, the dielectric hard mask layer 34 includes a silicon-containing dielectric material such as silicon oxide or silicon nitride, and can be anisotropically etched by a reactive ion etch process that employs a combination of CHF₃ and O₂. In another embodiment, the dielectric hard mask layer 34 can include a metallic material such as TiN or TaN, and can be etched by a reactive ion etch process that employs a Cl₂-based etch chemistry.

In one embodiment, the portion(s) of the carbon-based template layer 32 underlying the at least one opening 39 in the photoresist layer 37 can be removed by another anisotropic etch, which can be a reactive ion etch. The chemistry of the anisotropic etch is selected such that the anisotropic etch does not etch the physically exposed surfaces of the semiconductor substrate 8, or the physically exposed surfaces of the gate cap dielectrics 29 and the dielectric spacers 52. In one embodiment, the anisotropic etch can employ a N₂/H₂-based reactive ion etch, a CO₂-based reactive ion etch, a SO₂-based reactive ion etch, and/or a NH₃-based reactive ion etch.

The photoresist layer 37 can be consumed during the anisotropic etch of the carbon-based template layer 32, or can be removed after the anisotropic etch of the carbon-based template layer 32. The dielectric hard mask layer 34 functions as an etch stop layer during the removal of the photoresist layer 32.

The stack of the carbon-based template layer 32 and the dielectric hard mask layer 34 includes at least one cavity 65, i.e., at least one cavity, therein. Each of the at least one cavity 65 extends from the top surface of the dielectric hard mask layer 34 to a portion of the top surface of the semiconductor substrate 8 that is physically exposed between a pair of the plurality of protruding structures (25, 27, 29, 52). The carbon-based template layer 32 has a planar top surface located at, or above, the topmost surface of the plurality of protruding structures (25, 27, 29, 52).

A first sidewall SW1 of a cavity 65 among the at least one cavity 65 can overlie a top surface of a first protruding structure among the plurality of protruding structures (25, 27, 29, 52), and a second sidewall SW2 of the cavity 65 can overlie a top surface of a second protruding structure among the plurality of protruding structures (25, 27, 29, 52).

In one embodiment, a top surface of a third protruding structure located between the first protruding structure and the second protruding structure (e.g., the middle protruding structure located between the two outer protruding structures in FIGS. 4A and 4B) can be physically exposed upon the patterning of the stack (32, 34). In one embodiment, a first vertical planar sidewall VPS1 of a first dielectric spacer 52 and a second vertical planar sidewall VPS2 of a second dielectric spacer 52 are physically exposed within the cavity 65. In one embodiment, one or more of the at least one cavity 65 can have a rectangular horizontal cross-sectional area.

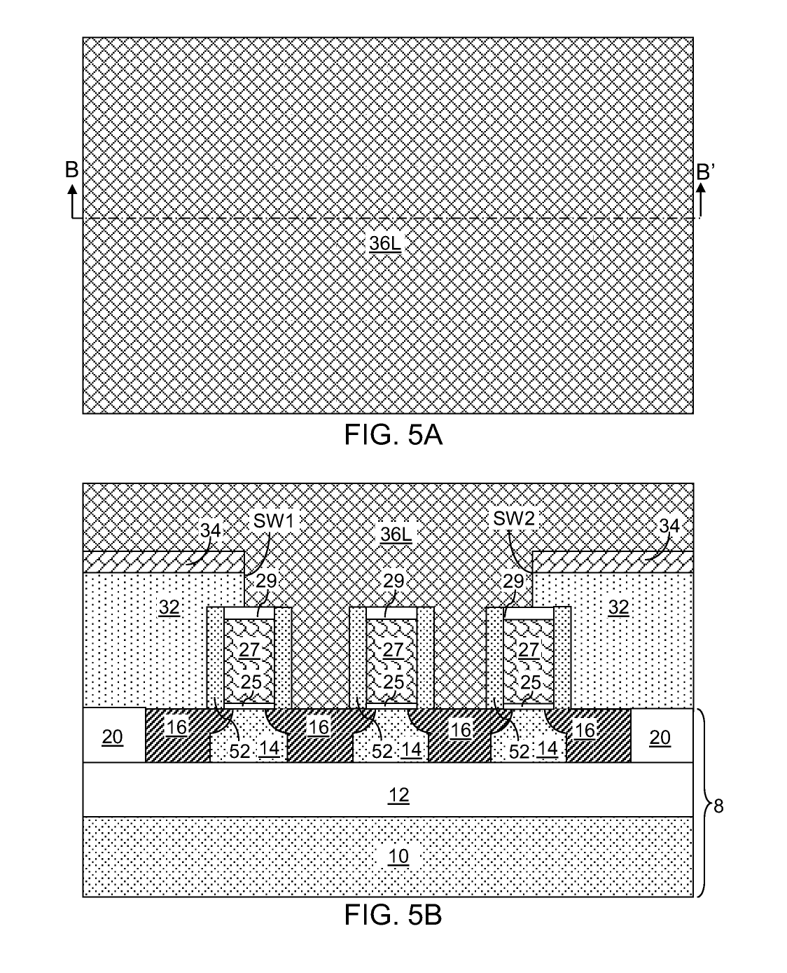

Referring to FIGS. 5A and 5B, at least one conductive material is deposited within the at least one cavity 65 in the dielectric hard mask layer 34 and the carbon-based template layer 32 to form a conductive material layer 36L. The at least one conductive material can include, for example, Ti, TiN, Ta, TaN, W, WN, Al, Ru, Pr, Cu, and combinations and/or alloys thereof. The at least one conductive material can be deposited, for example, by physical vapor deposition (PVD), chemical vapor deposition (CVD), electroplating, electroless plating, or combinations thereof.

The conductive material layer 36L is deposited over the entirety of the stack (32, 34) and within the at least one cavity 65 and directly on the physically exposed surfaces of portions of the top surface of the semiconductor substrate 8. In one embodiment, the conductive material layer 36L can contact outer surfaces of the dielectric spacers 52 within the at least one cavity 65. For example, the conductive material layer 36L can contact the outer surfaces of the dielectric spacers 52 of a protruding structure among the plurality of protruding structures (25, 27, 29, 52) located in a region between the first sidewall SW1 and the second sidewall SW2.

In one embodiment, a first portion of the conductive material layer 36L located between the topmost surface of the plurality of protruding structures (25, 27, 29, 52) and the top surface of the dielectric hard mask layer 34 can have a horizontal cross-sectional shape that coincides with the shape of a cavity 65 among the at least one cavity 65. In one embodiment, the horizontal cross-sectional shape can be rectangular.

In one embodiment, a second portion of the conductive material layer 36L underlying the first portion and located below the topmost surface of the plurality of protruding structures has a horizontal cross-sectional shape defined by a pair of parallel lines separated by a same distance as a distance between outer sidewalls of a pair of the dielectric spacers and a pair of edges that adjoin the pair of parallel lines and having same shapes as portions of the cavity 65.

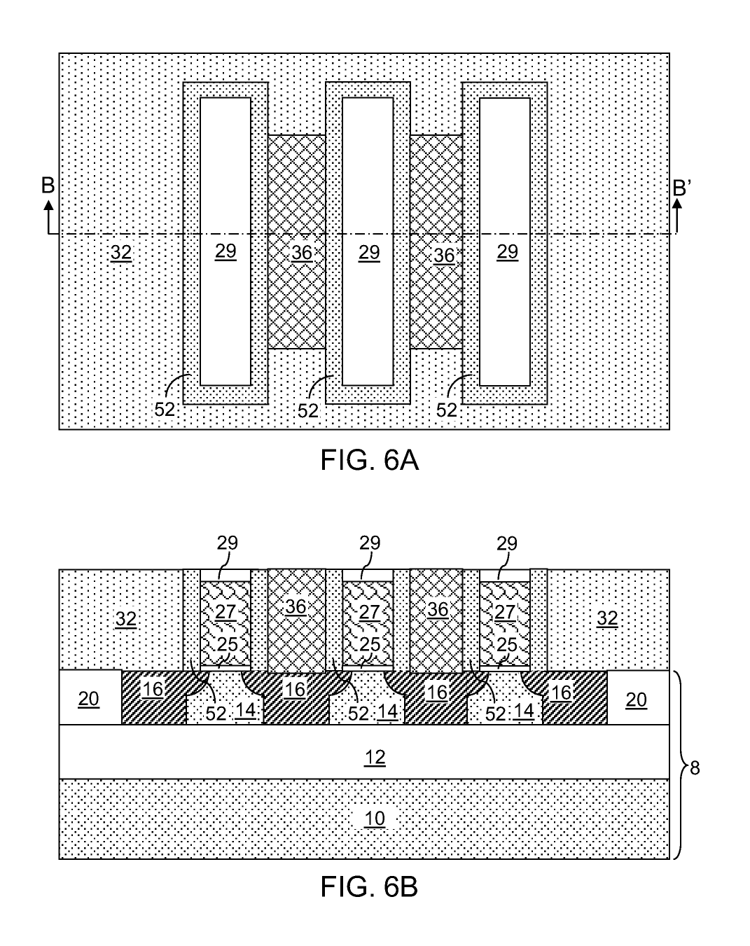

Referring to FIGS. 6A and 6B, the at least one conductive material of the conductive material layer 36L is planarized, for example, by chemical mechanical planarization (CMP). The conductive material layer 36L, the dielectric hard mask layer 34 and portions of the carbon-based template layer 32 are removed from above a horizontal plane. In one embodiment, the conductive material layer 36L, the dielectric hard mask layer 34 and portions of the carbon-based template layer 32 can be removed by planarization employing top surfaces of the plurality of protruding structures (25, 27, 29, 52) as stopping structures. In one embodiment, portions of the conductive material layer 36L can be removed from above the top surfaces of the gate cap dielectrics 29. In this case, the gate cap dielectrics 29 can be employed as stopping layers. Top surfaces of remaining portions of the carbon-based template layer 32 can be coplanar with the top surfaces of the plurality of protruding structures (25, 27, 29, 52). The remaining portions of the conductive material layer 36L are herein referred to as conductive material portions 36.

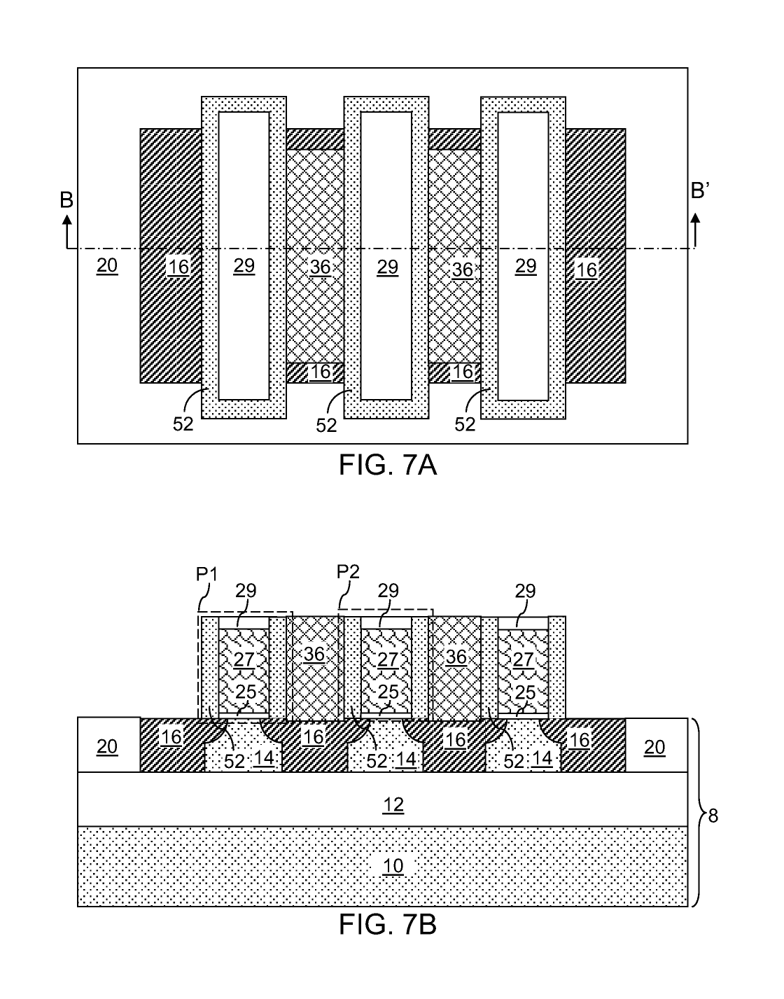

Referring to FIGS. 7A and 7B, the carbon-based template layer 32 is removed selective to the plurality of protruding structures (25, 27, 29, 52), the conductive material portions 36, and the semiconductor substrate 8. For example, the carbon-based template layer 32 can be removed by a reactive ion etch or a wet etch. Exemplary reactive ion etch processes that can be employed to remove the carbon-based template layer 32 include an N₂/H₂ plasma-based reactive ion etch process and an NH₃ plasma-based reactive ion etch process. An exemplary wet etch process that can be employed to remove the carbon-based template layer 32 include a wet etch employing dimethylformamide ((CH₃)₂NC(O)H, DMF).

A first protruding structure P1 is located on the semiconductor substrate 8 and includes a first conductive structure, i.e., a gate electrode 27, and a first dielectric spacer, i.e., the dielectric spacer 52 within the first protruding structure P1, laterally surrounding the first conductive structure. A second protruding structure P2 is located on the semiconductor substrate 8 and includes a second conductive structure, i.e., another gate electrode 27, and a second dielectric spacer, i.e., the dielectric spacer 52 within the second protruding structure P2, laterally surrounding the second conductive structure. A conductive material portion 36 can be in contact with a sidewall of the first dielectric spacer, and a sidewall of the second dielectric spacer, and can vertically extend from the top surface of the semiconductor substrate 8 and to the topmost surface of the first and second protruding structures (P1, P2). In one embodiment, the sidewall of the first dielectric spacer 52 can be located within a first vertical plane, and the sidewall of the second dielectric spacer can be located within a second vertical plane.

In one embodiment, the first protruding structure P1 can include a first gate stack, and the second protruding structure P2 can include a second gate stack. In one embodiment, the top surface of the semiconductor substrate 8 can includes a surface of a source/drain region 16, which can be a source region or a surface of a drain region of a field effect transistor. In one embodiment, each of the first and second gate stacks can include a vertical stack of a planar gate dielectric having a same (i.e., uniform) thickness throughout (i.e., a gate dielectric 25), a gate electrode 27, and a gate cap dielectric 29. Sidewalls of the planar gate dielectric, the planar gate electrode, and the gate cap dielectric can be vertically coincident among one another.

In one embodiment, a topmost surface of each conductive material portion 36 can be coplanar with the topmost surface of the first and second protruding structures (P1, P2). A horizontal cross-sectional area of each conductive material portion 36 can be substantially rectangular.

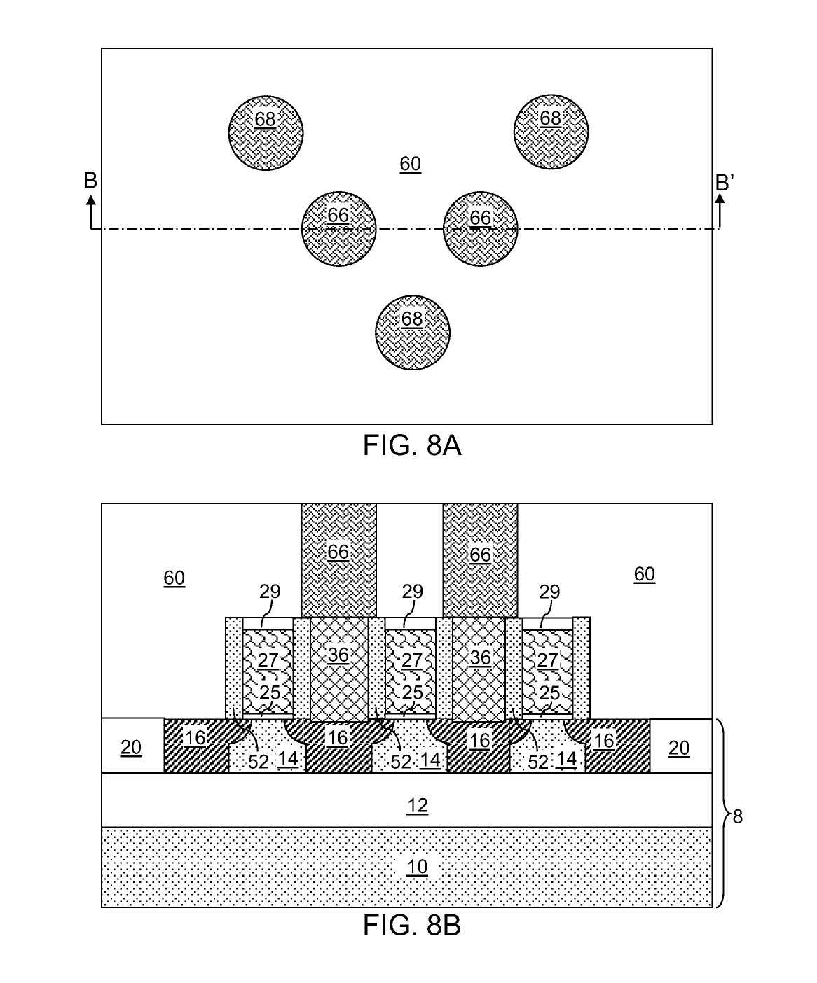

Referring to FIGS. 8A and 8B, a contact-level dielectric layer 60 is deposited over the plurality of protruding structures (25, 27, 29, 52) and the conductive material portions 36. The contact-level dielectric layer 60 includes at least one dielectric material, which can be silicon oxide, silicon nitride, silicon oxynitride, a dielectric metal oxide, porous or non-porous organosilicate glass, or combinations thereof. In one embodiment, the contact-level dielectric layer 60 can be homogeneous throughout the entirety thereof, and can contact the top surface of the semiconductor substrate 8. The contact-level dielectric layer 60 can be self-planarizing, or can be planarized, for example, by chemical mechanical planarization (CMP).

A planarized top surface of the contact-level dielectric layer 60 can be formed above the top surfaces of the conductive material portions 36 and the plurality of protruding structures (25, 27, 29, 52). Contact via holes can be formed through the contact-level dielectric layer 60, for example, over the conductive material portions 36 and the gate electrodes 27. Top surfaces of the conductive material portions 36 and the gate electrodes 27 are physically exposed at the bottom of the contact via holes. The contact via holes are filled with a conductive material. Excess conductive material deposited above the top surface of the contact-level dielectric layer 60 is removed, for example, by chemical mechanical planarization. Remaining portions of the conductive material within the contact via holes constitute various contact via structures, which can include first contact via structures 66 that vertically contact top surfaces of the conductive material portions 36 and second contact via structures 68 that contact top surfaces of the gate electrodes 27. The first and second contact via structures (66, 68) can have top surfaces that are coplanar with the top surface of the contact-level dielectric layer 60.

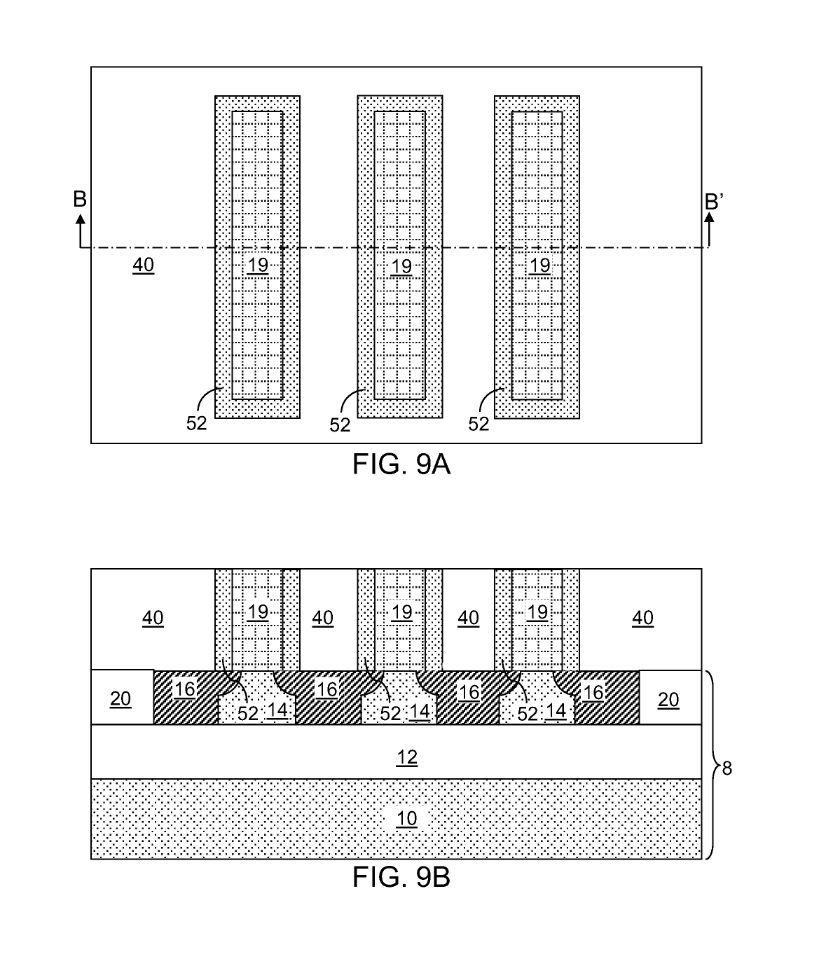

Referring to FIGS. 9A and 9B, a variation of the first exemplary structure includes disposable gate structures 19 that are formed on the top surface of the semiconductor substrate 8 according to a replacement gate scheme. A dielectric spacer 52 can be formed on sidewalls of each disposable gate structure 19.

A disposable material is deposited over the semiconductor substrate 8, the plurality of disposable gate structures 19, and the plurality of dielectric spacers 52. The disposable material can be planarized employing the plurality of disposable gate structures 19 as stopping structures. A remaining portion of the disposable material constitutes a planarization material layer 40. In one embodiment, the planarization material layer 40 can include a semiconductor material such as germanium or a silicon germanium alloy including germanium at an atomic concentration greater than 50%, and the source/drain regions 16 can include doped silicon. In another embodiment, the planarization material layer 40 can include organosilicate glass that can be removed selective to the dielectric materials of the gate cap dielectrics 29 and the dielectric spacers 52.

The planarization material layer 40 is subsequently planarized employing the top surfaces of the dielectric gate caps 29 as stopping layers. A layer is formed, which has a planar top surface and complementarily filled with the planarization material layer 40, the plurality of disposable gate structures, and the plurality of dielectric spacers 52 surrounding each of the plurality of disposable gate structures 19.

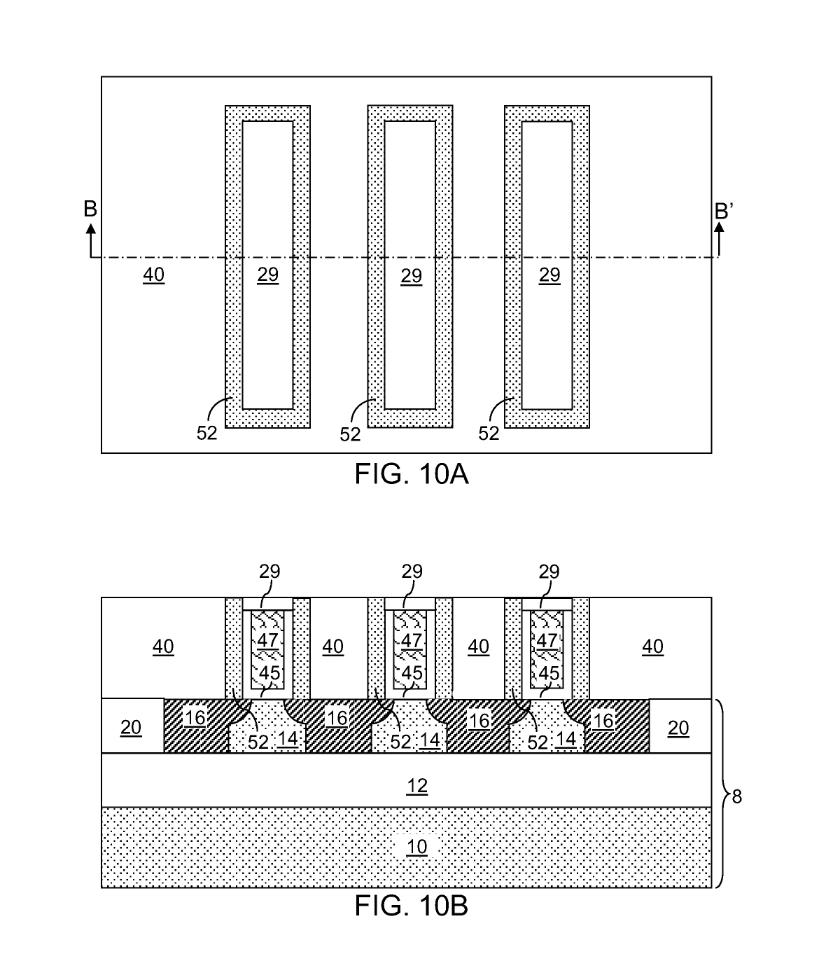

Referring to FIGS. 10A and 10B, gate cavities are formed by removing the plurality of disposable gate structures 19 selective to the planarization material layer 40 and the dielectric spacers 52. The gate cavities are subsequently filled with replacement gate structures. For example, each replacement gate stack can include a gate dielectric 45, a gate electrode 47, and a gate cap dielectric 29.

In one embodiment, the replacement gate stacks (45, 47, 29) can be formed by depositing a gate dielectric layer in the gate cavities and the top surface of the planarization material layer 40, by filling the gate cavities with at least one conductive material, by removing portions of the gate dielectric layer and the at least one conductive material from above the top surface of the planarization material layer 40, by recessing the remaining portions of the gate dielectric layer and the at least one conductive material relative to the top surface of the planarization material layer 40, and by depositing a gate cap dielectric 29 within each recessed region below the top surface of the planarization material layer 40. The gate cap dielectrics 29 can be formed by filling the recessed regions with a dielectric material and removing excess portions of the dielectric material from above the top surface of the planarization material layer 52, for example, by chemical mechanical planarization.

In one embodiment, each gate dielectric 45 can be a U-shaped gate dielectric that includes a lower horizontal portion and upper vertical portions. Each of the gate electrodes 47 can be laterally surrounded by one of the U-shaped gate dielectrics. Sidewalls of each gate cap dielectric 29 can be vertically coincident with outer vertical sidewalls of an underlying U-shaped gate dielectric.

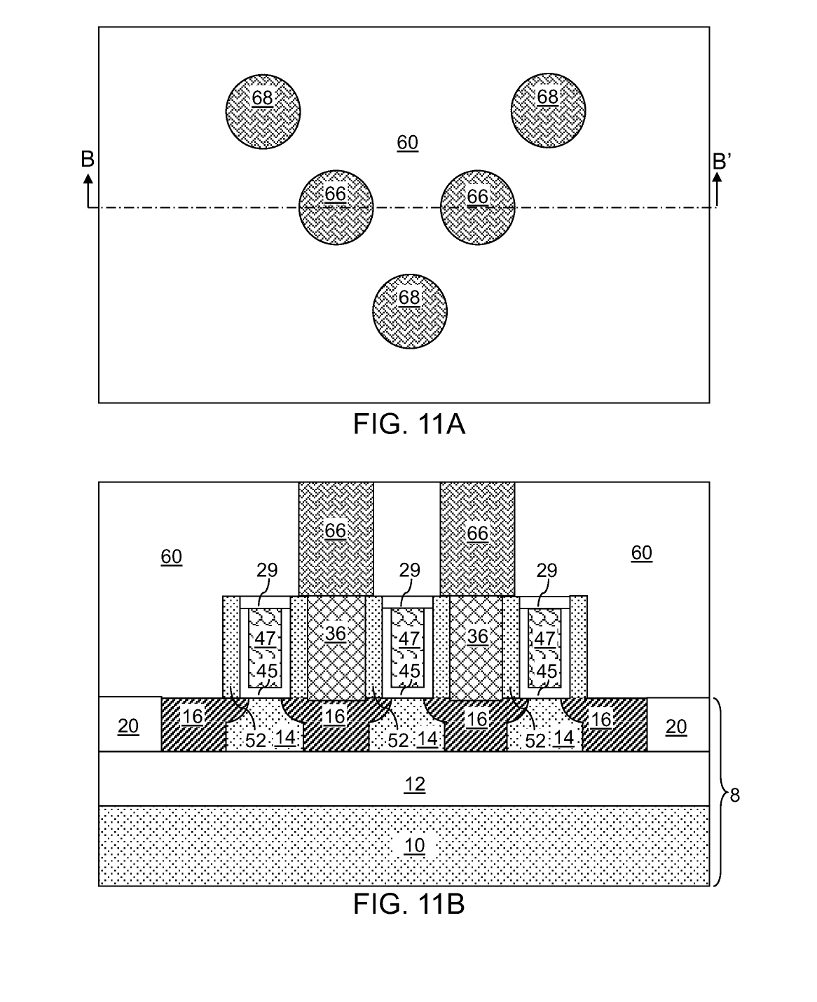

Referring to FIGS. 11A and 11B, the planarization material layer 40 is removed from above the semiconductor substrate 8. A plurality of protruding structures includes replacement gate stacks (45, 47, 49) and the dielectric spacers 52. Thus, the replacement gate structures (45, 47, 49) constitute portions of a plurality of protruding structures upon removal of the planarization material layer 40 from above the semiconductor substrate. The processing steps of FIGS. 1A, 1B, 2A, 2B, 3A, 3B, 4A, 4B, 5A, 5B, 6A, 6B, 7A, 7B, 8A, 8B, 9A, 9B, 10A, and 10B can be subsequently performed in the variation of the first exemplary semiconductor structure in which the plurality of protruding structures (45, 47, 29, 52) substitutes the plurality of protruding structures (25, 27, 29, 52).

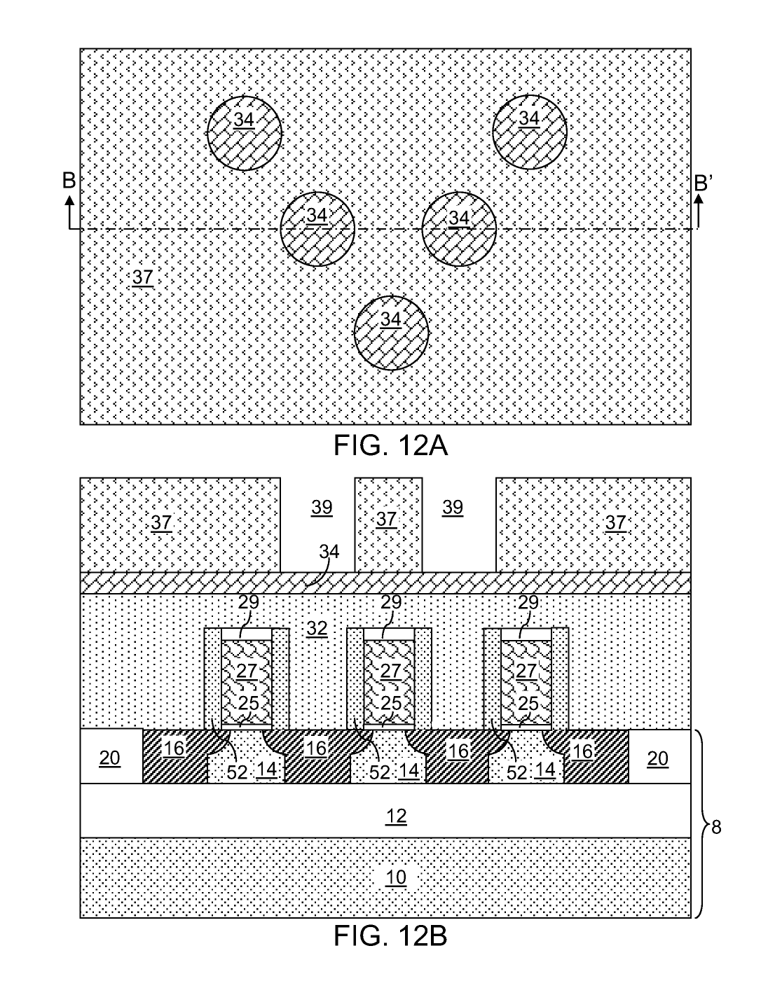

Referring to FIGS. 12A and 12B, a second exemplary semiconductor structure according to a second embodiment of the present disclosure can be derived from the first exemplary structure of FIGS. 2A and 2B by forming at least one opening 39 in the photoresist layer 37 such that one or more of the at least one opening 39 has an elliptical horizontal cross-sectional area.

The pattern of the at least one opening 39 can be selected such that the some opening 39s are formed in areas in which contact via structures that contact surfaces of the semiconductor substrate 8 are to be subsequently formed. In one embodiment, an area of an opening 39 can laterally extend from a sidewall of a dielectric spacer 52 within a first protruding structure (25, 27, 29, 52) to a sidewall of another dielectric spacer 52 within a second protruding structure (25, 27, 29, 52) that is laterally spaced from the first protruding structure (25, 27, 29, 52) at least by an interface between the semiconductor substrate 8 and the carbon-based template layer 32. In one embodiment, one or more of the at least one opening 39 can have an elliptical horizontal cross-sectional area. As used herein, a shape is “elliptical” if the shape is a circle or an ellipse.

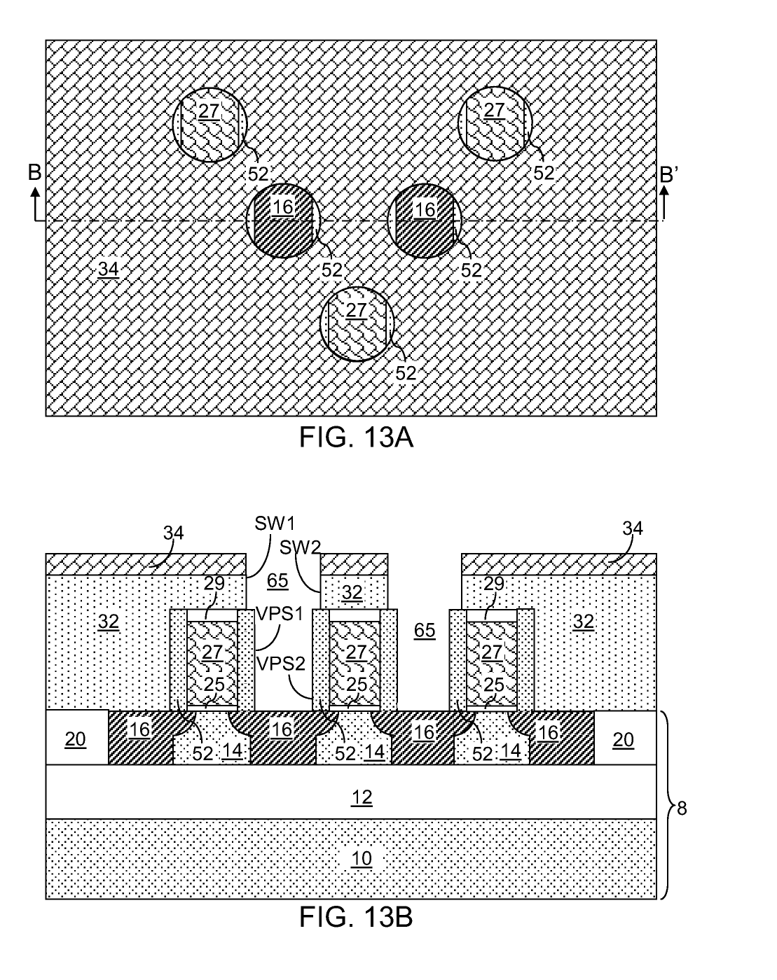

Further, the pattern of the at least one opening 39 can be selected such that the area of some other opening 39s are formed in areas in which contact via structures that contact gate electrodes 27 are to be subsequently formed. (See the areas in FIG. 13A that show physically exposed portions of gate electrodes 27.)

Referring to FIGS. 13A and 13B, the pattern in the photoresist layer 37 is transferred through the dielectric hard mask layer 34 and the carbon-based template layer 32 by an anisotropic etch, which can be a reactive ion etch. The same etch chemistry can be employed as in the first embodiment. Further, the etch chemistry for the transfer of the pattern can be selected so that the gate electrodes 27 are not removed by the anisotropic etch. The photoresist layer 37 can be consumed during the anisotropic etch of the carbon-based template layer 32, or can be removed after the anisotropic etch of the carbon-based template layer 32. The dielectric hard mask layer 34 functions as an etch stop layer during the removal of the photoresist layer 32.

The stack of the carbon-based template layer 32 and the dielectric hard mask layer 34 includes at least one cavity 65, i.e., at least one cavity 65, therein. Each of the at least one cavity 65 extends from the top surface of the dielectric hard mask layer 34 to a portion of the top surface of the semiconductor substrate located 8 that is physically exposed between a pair of the plurality of protruding structures (25, 27, 29, 52). The carbon-based template layer 32 has a planar top surface located at, or above, the topmost surface of the plurality of protruding structures (25, 27, 29, 52).

A first sidewall SW1 of a cavity 65 can overlie a top surface of a first protruding structure among the plurality of protruding structures (25, 27, 29, 52), and a second sidewall SW2 of the cavity 65 can overlie a top surface of a second protruding structure among the plurality of protruding structures (25, 27, 29, 52). In one embodiment, a first vertical planar sidewall VPS1 of a first dielectric spacer and a second vertical planar sidewall VPS2 of a second dielectric spacer are physically exposed within the cavity. In one embodiment, the first vertical planar sidewall VPS1 and the second vertical planar sidewall VPS2 can be parallel to each other.

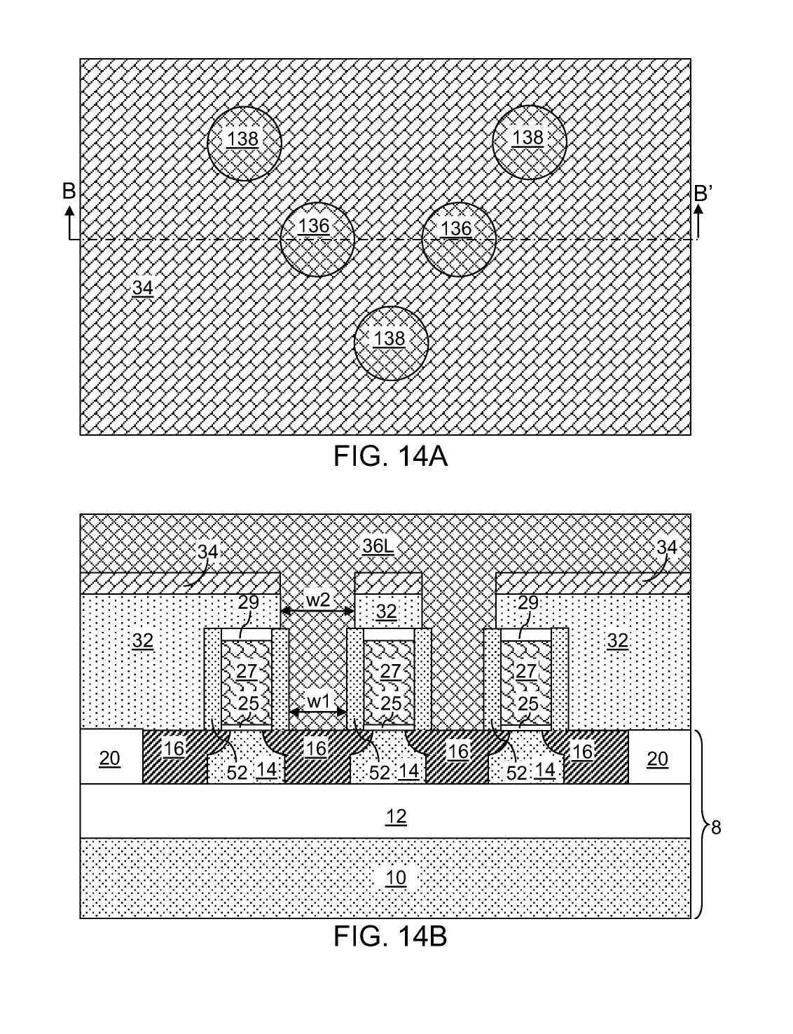

Referring to FIGS. 14A and 14B, the cavities 65 are filled with the at least one conductive material in the same manner as in the processing steps of FIGS. 5A and 5B to form a conductive material layer 36L. The at least one conductive material is deposited within the cavities directly above the source/drain regions 16 and the cavities overlying gate electrodes 27. The conductive material layer 36L includes downward-protruding portions that fill the various cavities 65. In one embodiment, at lest one downward-protruding portion can have a first width w1 between a pair of parallel sidewalls located at a lower portion thereof, and a second width w2 between a pair of elliptical sidewalls. In one embodiment, the second width w2 can be a diameter, or a major axis or a minor axis of an ellipse.

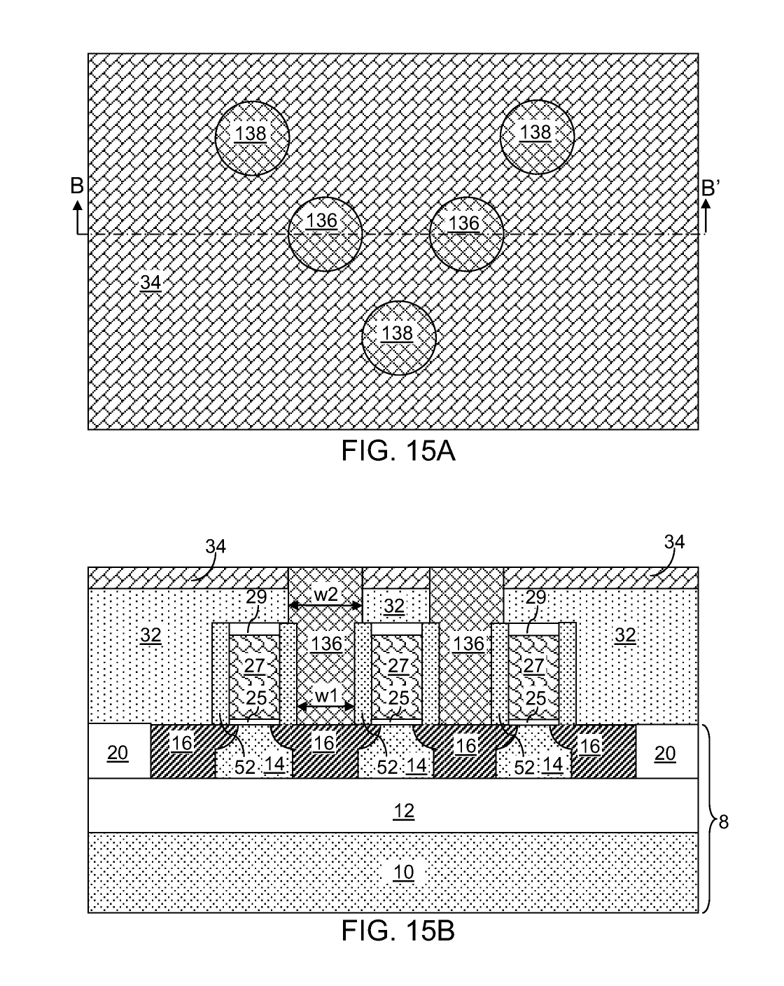

Referring to FIGS. 15A and 15B, the at least one conductive material of the conductive material layer 36L is planarized, for example, by chemical mechanical planarization (CMP). Portions of the conductive material layer 36L are removed from above a horizontal plane. In one embodiment, the conductive material layer 36L can be removed by planarization employing the dielectric hard mask layer 34 as a stopping layer. Top surfaces of remaining portions of the carbon-based template layer 32 can be coplanar with the top surface of the dielectric hard mask layer 34. The remaining portions of the conductive material layer 36L are herein referred to as conductive material portions 136 and gate-contact conductive material portions 138.

Topmost surfaces of the conductive material portions 136 are located above the topmost surfaces of the plurality of protruding structures (45, 47, 29, 52). In one embodiment, a horizontal cross-sectional shape of a lower portion the conductive material portion 136 located below the topmost surface of the plurality of protruding structures (45, 47, 29, 52) can be the same as a horizontal cross-sectional shape of an upper portion of the conductive material portion 136 less shapes of horizontal cross-sectional areas of a first dielectric spacer and a second dielectric spacer that the conductive material portion 136 laterally contacts. (See the shape of the physically exposed portions of source/drain regions 16 in FIG. 13A).

In one embodiment, the horizontal cross-sectional shape of the upper portion of the conductive material portion 136 can be the shape of an ellipse. As used herein, an “ellipse” can be a circle or an ellipse having a non-zero ellipticity. In one embodiment, a horizontal cross-sectional area of a lower portion of the conductive material portion 136 can have a shape that includes a pair of elliptical portions located on opposite sides and joined to each other by a pair of straight lines defining a rectangular portion. The horizontal cross-sectional area can be the same shape as a visible portion of a source/drain region 16 as illustrated in FIG. 13A. The area of the pair of elliptical portions (located at the top end and the bottom end of the shape of a source/drain region 16 as illustrated in FIG. 13A) overlap with the area of the shape of the ellipse in a top-down view. Thus, the pair of elliptical portions of the lower portion of a conductive material portion 136 can be vertically coincident with sidewalls of the upper portion of the conductive material portion 136.

Additional conductive material portions are formed directly on top surfaces of the gate electrodes 27. The additional conductive material portions are herein referred to as gate-contact conductive material portions 138, which have the same composition as the conductive material portions 136.

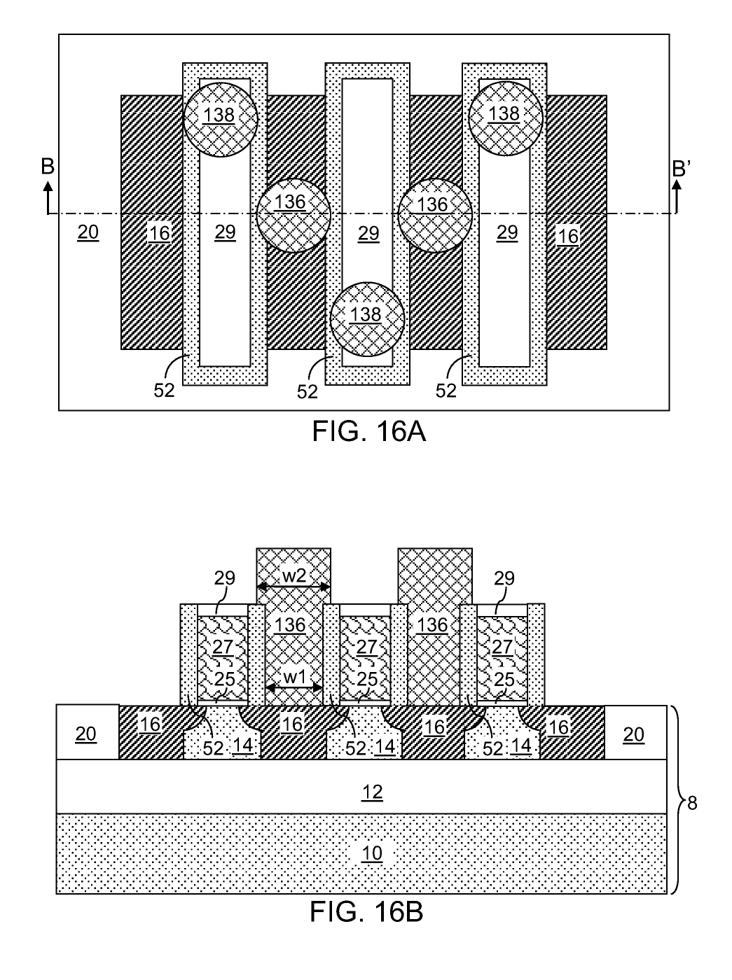

Referring to FIGS. 16A and 16B, the dielectric hard mask layer 34 is removed by a wet etch or a dry etch selective to the conductive material portions 136 and the gate-contact conductive material portions 138. The carbon-based template layer 32 may be partially removed, fully removed, or not removed during the removal of the dielectric hard mask layer 34. Any remaining portion of the carbon-based template layer 32 can be removed employing the same methods as in the first embodiment.

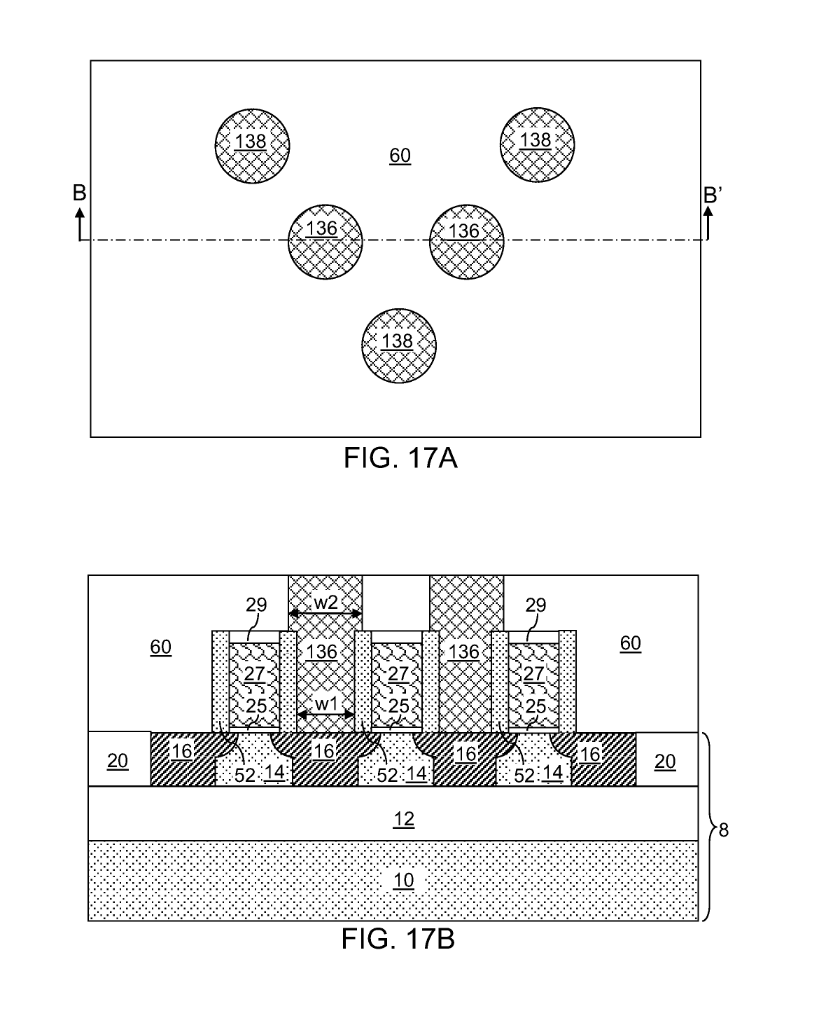

Referring to FIGS. 17A and 17B, a contact-level dielectric layer 60 is deposited over the plurality of protruding structures (45, 47, 29, 52) and the conductive material portions 136. The contact-level dielectric layer 60 can include the same material as in the first embodiment. In one embodiment, the contact-level dielectric layer 60 can be homogeneous throughout the entirety thereof, and can contact the top surface of the semiconductor substrate 8. The contact-level dielectric layer 60 can be self-planarizing, or can be planarized, for example, by chemical mechanical planarization (CMP). In one embodiment, the conductive material portions 136 and the gate-contact conductive material portions 138 can be employed as stopping structures for the CMP process. A planarized top surface of the contact-level dielectric layer 60 can be formed at the same height as the top surfaces of the conductive material portions 136 and the gate-contact conductive material portions 138.

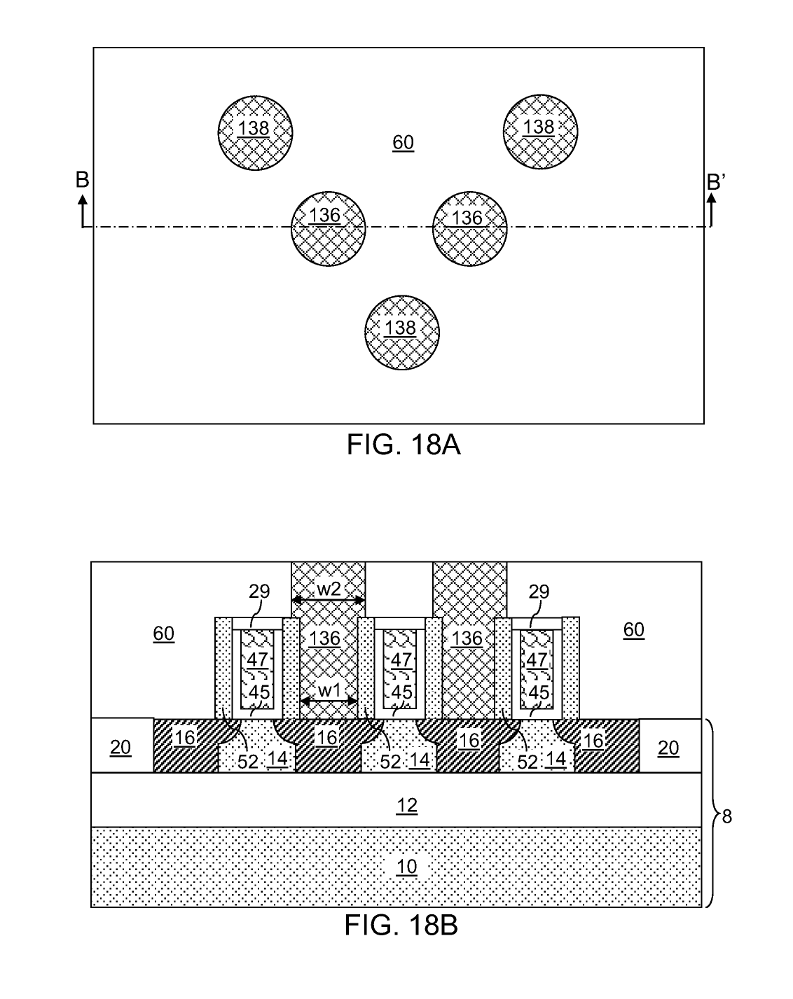

Referring to FIGS. 18A and 18B, a variation of the second exemplary semiconductor structure can be derived by forming the structures illustrated in FIGS. 9A, 9B, 10A, and 10B, and by substituting the structure derived by removing the planarization material layer 40 of FIGS. 10A and 10B for the structure illustrated in FIGS. 1A and 1B, and subsequently performing the processing steps of the second embodiment.

The methods of the present disclosure provide lesser erosion of dielectric spacers 52 relative to methods known in the art because anisotropic etch processes for carbon-containing materials can provide higher selectivity than anisotropic etch processes for conventional dielectric materials such as silicon oxide and silicon nitride. Thus, self-aligned contact structures can be formed with less electrical shorting to conductive structures within protruding structures such as gate electrodes of field effect transistors.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

What is claimed is:

1. A method of forming a semiconductor structure comprising:
forming a plurality of protruding structures on a semiconductor substrate, wherein each of said plurality of protruding structure includes a conductive structure and a dielectric spacer laterally surrounding said conductive structure;
forming a stack of a carbon-based template layer and a dielectric hard mask layer over said semiconductor substrate;
patterning said stack by forming at least one opening therein, wherein each of said at least one opening extends from a top surface of said dielectric hard mask layer to a top surface of said substrate; and
forming a conductive material layer over an entirety of said stack and within said at least one opening and directly on a portion of said top surface of said substrate.

2. The method of claim 1, wherein a first sidewall of an opening among said at least one opening overlies a first protruding structure among said plurality of protruding structures, and a second sidewall of said opening overlies a second protruding structure among said plurality of protruding structures upon said patterning of said stack.

3. The method of claim 2, wherein a top surface of a third protruding structure located between said first protruding structure and said second protruding structure is physically exposed upon said patterning of said stack.

4. The method of claim 2, wherein a first vertical planar sidewall of a first dielectric spacer and a second vertical planar sidewall of a second dielectric spacer are physically exposed within said opening.

5. The method of claim 1, wherein one of said at least one opening has a rectangular horizontal cross-sectional area.

6. The method of claim 1, wherein one of said at least one opening has an elliptical horizontal cross-sectional area.

7. The method of claim 1, further comprising planarizing said conductive material layer employing top surfaces of said plurality of protruding structures as stopping structures.

8. The method of claim 1, further comprising removing said hard mask layer and portions of said carbon-based template layer, wherein a top surface of a remaining portion of said carbon-based template layer is coplanar with a top surface of said plurality of protruding structures.

9. The method of claim 1, further comprising planarizing said conductive material layer employing said dielectric hard mask layer as a stopping layer.

10. The method of claim 1, further comprising forming a conductive material portion by removing portions of said conductive material layer from above a horizontal plane.

11. The method of claim 10, further comprising:
removing said dielectric hard mask layer; and
removing said carbon-based template layer.

12. The method of claim 11, further comprising depositing a contact-level dielectric layer after removal of said carbon-based template layer.

13. The method of claim 12, further comprising planarizing said contact-level dielectric layer employing said conductive material portion as a stopping structure.

14. The method of claim 12, further comprising planarizing said contact-level dielectric layer to form a planarized top surface of said contact-level dielectric layer above a topmost surface of said conductive material portion.

15. The method of claim 14, further comprising:
forming a contact via hole within said contact-level dielectric layer and above said conductive material portion; and
forming a contact via structure by filling said contact via hole with a conductive material.

16. The method of claim 1, wherein said forming of said plurality of protruding structures comprises forming gate stacks, wherein each of said gate stacks comprises at least a gate dielectric and a gate electrode.

17. The method of claim 16, further comprising forming a source/drain region within said semiconductor substrate, wherein said portion of said top surface of said semiconductor substrate comprises a surface of said source/drain region.

18. The method of claim 16, wherein said forming of said plurality of protruding structures comprises:
forming a planar gate dielectric layer on said top surface of said semiconductor substrate;
forming a planar gate electrode layer on said planar gate dielectric layer; and
patterning said planar gate electrode layer and said planar gate dielectric layer, wherein remaining portions of said planar gate electrode layer constitute said conductive structures.

19. The method of claim 18, further comprising:
depositing a conformal dielectric material layer on sidewalls of said conductive structures; and
removing horizontal portions of said conformal dielectric material layer by anisotropically etching said conformal dielectric material layer, wherein remaining portions of said conformal dielectric material layer constitute said dielectric spacers.

20. The method of claim 16, wherein said forming of said plurality of protruding structures comprises:
forming a layer having a planar top surface and complementarily filled with a planarization material layer, a plurality of disposable gate structures, and a plurality of dielectric spacers surrounding each of said plurality of disposable gate structures;
forming gate cavities by removing said plurality of disposable gate structures;
filling said gate cavities with replacement gate structures; and
removing said planarization material layer from above said semiconductor substrate, wherein said replacement gate structures constitute portions of said plurality of protruding structures upon removal of said planarization material layer from above said semiconductor substrate.

21. The method of claim 20, wherein said forming of said layer having said planar top surface comprises:
forming said plurality of disposable gate structures on said semiconductor stacks;
depositing a disposable material over said plurality of disposable gate structures; and
planarizing said disposable material employing said plurality of disposable gate structures as stopping structures, wherein a remaining portion of said disposable material constitutes said planarization material layer.

22. The method of claim 1, wherein said carbon-based template layer comprises an inorganic carbon-containing material.

23. The method of claim 22, wherein said carbon-based template layer comprises at least one of diamond-like carbon (DLC), amorphous carbon, and carbon nitride.

24. The method of claim 1, wherein said carbon-based template layer comprises an organic carbon-containing polymer.

25. The method of claim 24, wherein said carbon-based template layer comprises a material selected from a naphthalene-based polymer, a cured poly(aryl acetylene) polymer or oligomer, a cured poly(aryl diacetylene) polymer or oligomer, a polyimide-based polymer, and a fluororocarbon-based polymer.
